(19) United States
(12) Patent Application Publication
(10) Pub. No.: US 2006/0162656 A1
(43) Pub. Date: Jul. 27, 2006

(54) Reduced volume, high conductance process chamber

(75) Inventor: Steven T. Fink, Mesa, AZ (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/521,444

(22) PCT Filed: Jul. 30, 2003
(86) PCT No.: PCT/US03/19884

§ 371 Date: Jan. 14, 2005

Related U.S. Application Data
(60) Provisional application No. 60/399,380, filed on Jul. 31, 2002.

(51) Int. Cl. C23C 16/00; C23F 1/00; H05H 1/24

(52) U.S. Cl. 118/715; 118/723 R; 216/67; 427/569

(57) ABSTRACT

A vacuum processing apparatus including a process chamber having a plurality of pumping ports, and a plurality of pumping cells each connected to a respective pumping port of the plurality of pumping ports. The plurality of pumping ports is preferably located on a lower wall of the process chamber adjacent to a process chamber volume. A process chamber is also provided that includes a lower wall and a side wall, where the side wall has a height of about four inches. The vacuum processing apparatus further includes a chamber liner configured to displace open volume within the process chamber.

### CROSS-REFERENCE TO RELATED APPLICATIONS

This application is related to and claims priority to pending application 60/399,380, entitled “Reduced volume, high conductance process chamber,” Attorney docket no. 214458US6YA PROV, filed Jul. 31, 2002. The contents of this application is incorporated herein by reference.

### BACKGROUND OF THE INVENTION

1. Field of the Invention

The present invention generally relates to process chambers used to process objects such as semiconductor wafers.

2. Discussion of the Background

The semiconductor manufacturing industry and the semiconductor manufacturing equipment industry represent multi-billion dollar industries. Under conventional manufacturing processes, integrated circuits are fabricated using very expensive machines. In most integrated circuit fabrication machines used today, one of the most expensive components is a process chamber.

The process chamber is typically a fairly large component with complex machined features on many surfaces. In order to perform sufficiently during the manufacturing process, the process chamber must be clean and must be capable of functioning in high vacuum and ultra high vacuum ranges. In most cases, the process chamber is machined from a single, large billet of raw material. However, the use of a large billet of raw material is expensive and most of this material is subsequently machined away when fabricating the part.

### SUMMARY OF THE INVENTION

In an effort to provide an improved process chamber, the present invention provides an arrangement that generally reduces cost of manufacturing the process chamber, and reduces open volume within the process chamber thereby increasing conductance within the process chamber.

Accordingly, the present invention advantageously provides a plasma chamber including a lower wall and a side wall, where the side wall has a height of at most about four inches.

Additionally, the present invention advantageously provides a plasma apparatus including a plasma chamber having a plurality of pumping ports, and a plurality of pumping cells each connected to a respective pumping port of the plurality of pumping ports.

The present invention further advantageously provides a method of making an improved process chamber including the step of making the process chamber with a lower wall and a side wall, where the side wall has a height of at most about four inches.

Furthermore, the present invention advantageously provides a method of making an improved process chamber including the steps of providing a plurality of pumping ports in the process chamber, and connecting a respective pumping cell to each of the plurality of pumping ports.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIG. 1 is a side, partial cross-sectional view of a plasma etching apparatus having a plasma chamber according to an embodiment of the present invention;

FIG. 2 is a perspective view of the vacuum processing apparatus depicted in FIG. 1 according to an embodiment of the present invention;

FIGS. 3A-3D are top views of various pumping port configurations with respect to a chuck assembly;

FIG. 4A is a side cross-sectional view of a plate stock used to form the process chamber according to a first embodiment of the present invention;

FIG. 4B is a side cross-sectional view of a process chamber formed using the plate stock of FIG. 4A;

FIG. 5A is a side cross-sectional view of a mold used to form a process chamber according to a second embodiment of the present invention;

FIG. 5B is a side cross-sectional view of the mold of FIG. 5A filled with material used to form the process chamber according to the second embodiment of the present invention;

FIG. 6A is an exploded perspective view of component parts of a process chamber according to a third embodiment of the present invention; and

FIG. 6B is an assembled side view of the component parts depicted in FIG. 6A.

### DETAILED DESCRIPTION OF THE INVENTION

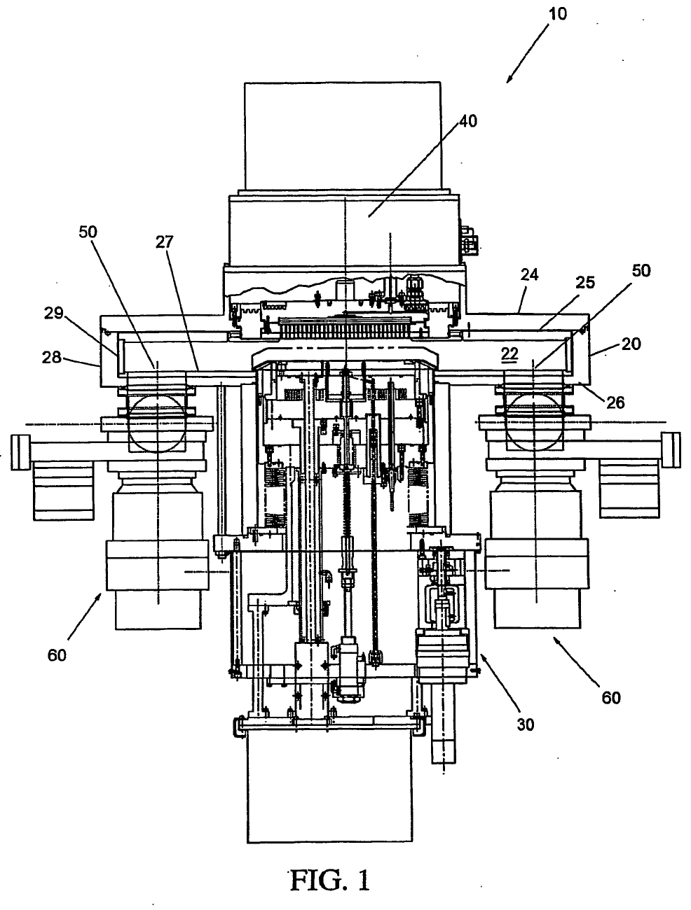

FIG. 1 depicts a preferred embodiment of a vacuum processing apparatus 10 according to the present invention. The vacuum processing apparatus 10 includes a process chamber 20 that defines a processing environment or process chamber volume 22, which is generally sealed from the environment outside of the process chamber 20. The process chamber 20 can, for example, facilitate processing with or without a processing plasma. The process chamber 20 generally has a chuck assembly 30 mounted therein. The chuck assembly 30 is configured to hold a substrate, such as a semiconductor wafer or a liquid crystal display (LCD), during the processing operation. The process chamber 20 and the associated chuck assembly 30 can, for example, be configured for processing substrates of diameter 200 mm, 300 mm, and larger.

The process chamber 20 can further include an upper electrode assembly 40 mounted opposite the chuck assembly 30. In an embodiment of the present invention, the upper electrode assembly 40 can be electrically biased to facilitate the formation of plasma. Alternately, the upper electrode assembly 40 is maintained at an electrical potential equivalent to that of the processing chamber 20. For example, processing chamber 20 and the upper electrode assembly 40 can be electrically connected to ground potential. In another embodiment, upper electrode assembly 40 can comprise an antenna.

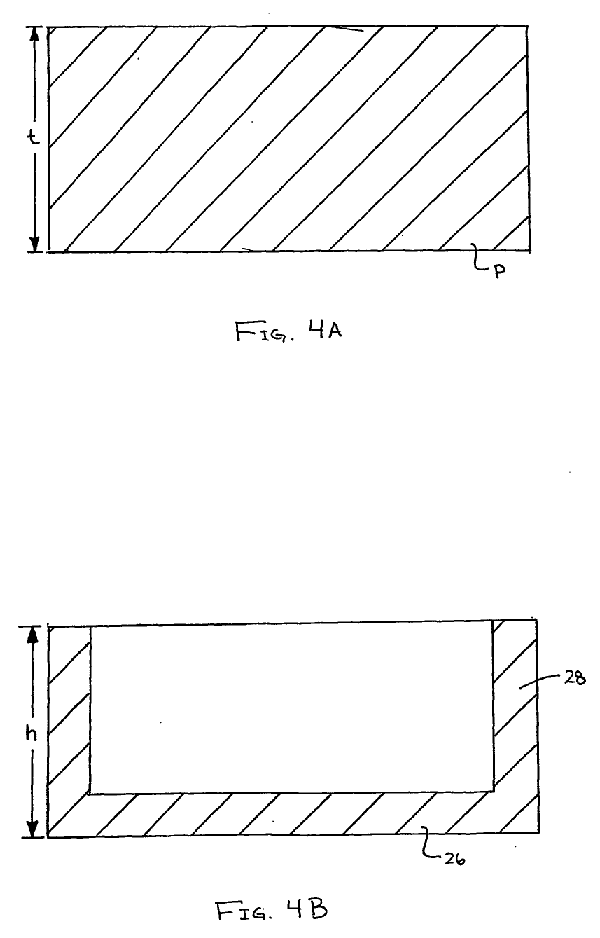

The process chamber 20 has an upper wall 24, a lower wall 26, and a side wall 28. The lower wall 26 and the side wall 28 are preferably formed of a single unit of material. The process chamber 20 can, for example, be made of plate stock having a thickness of about four inches. The plate stock is preferably aluminum, such as aluminum 6061-T651 plate-stock, although other materials can be used. FIG. 4A depicts a cross-sectional view of a solid piece of plate stock P having a thickness t of about four inches. The plate stock can be machined to form a bottom section of the process chamber as depicted in FIG. 4B. FIG. 4B depicts a cross-sectional view of the machined bottom section of the process chamber having the lower wall 26 and side wall 28 having a height of at most about four inches.

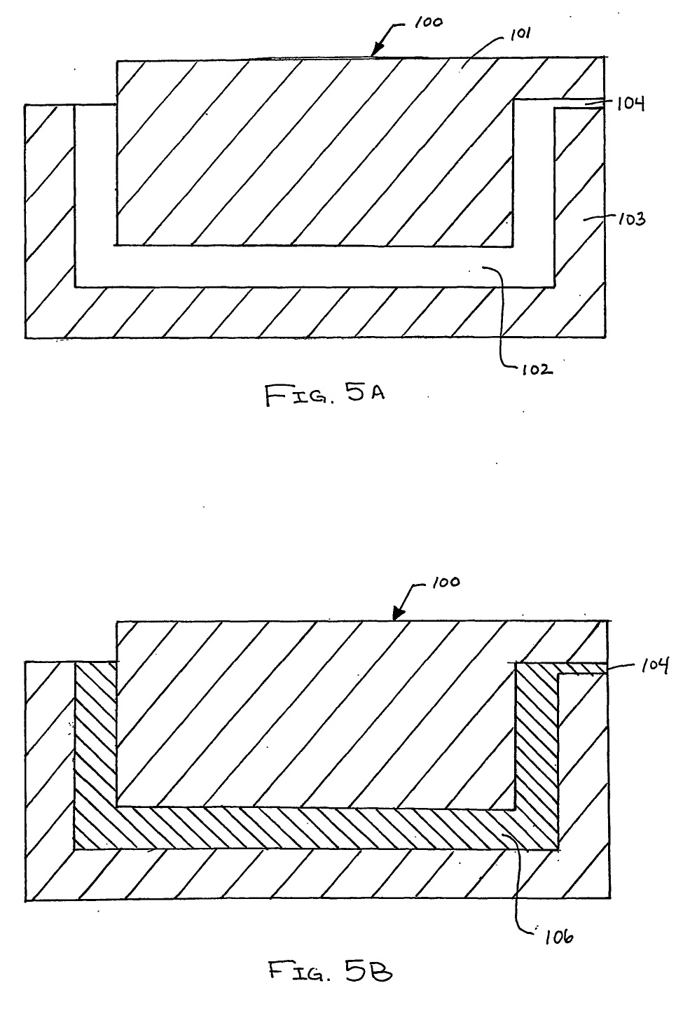

Alternatively, the bottom section of the process chamber can be formed in the manner depicted in FIGS. 5A and 5B. FIG. 5A depicts a cross-sectional view of a mold 100 used during a molding process to form the bottom section of the process chamber. The mold 100 includes an upper mold 101 and a lower mold 103, which when joined together define a cavity 102 therebetween that is generally of the shape of the bottom section of the process chamber. The cavity 102 has an inlet 104 that receives the molten material used to form the bottom section of the process chamber. Molten material is injected within the inlet to fill the cavity 102 as depicted in FIG. 5B, and then the molten material is cooled and solidified to form a rough product 106. The rough product 106 is then removed from the mold 100 by separating the upper mold 101 and the lower mold 103, and the rough product 106 is machined slightly to form the bottom section of the process chamber including the lower wall 26 and side wall 28.

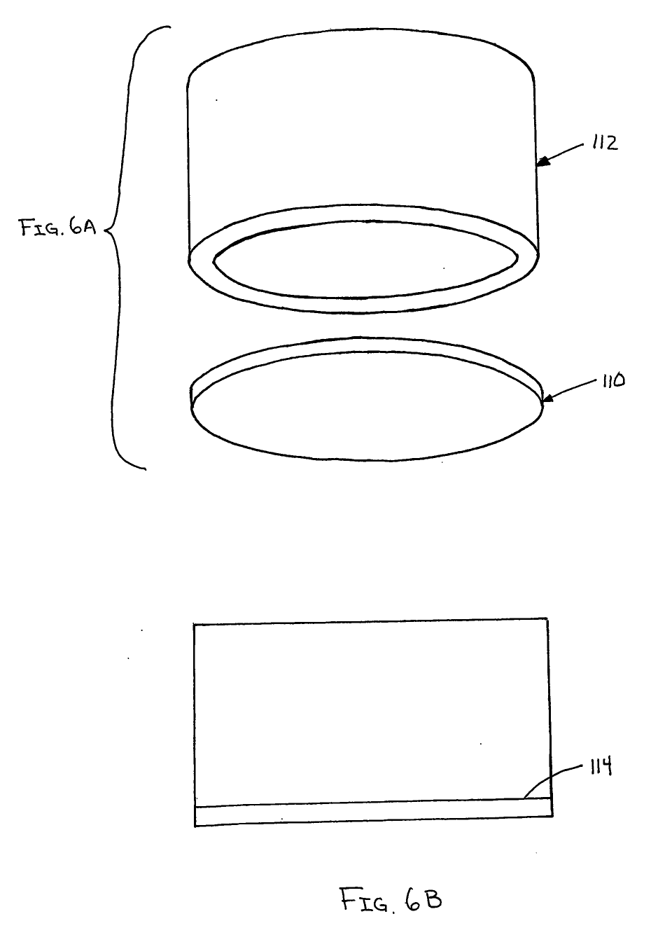

Alternatively, as shown in FIG. 6A, the bottom section of the process chamber can be formed by joining a plate 110, which forms the lower wall, and a cylindrical part 112, which forms the side wall. FIG. 6A depicts an exploded perspective view of the plate 110 and the cylindrical part 112. The cylindrical part 112 can be, for example, a rolled cylinder (or rolled ring forging). The plate 110 and the cylindrical part 112 can be joined by welding or another process along joint 114, as depicted in FIG. 6B.

The upper wall 24 can be positioned on a top edge of the side wall 28 as depicted in FIG. 1 and sealed thereto to act as a lid. The seal formed between the top edge of the side wall 28 and the upper wall 24 can be non-permanent, i.e. the seal is formed via an o-ring and an o-ring groove formed in at least one of the side wall 28 and the upper wall 24. For example, fastening devices (not shown) extending through the upper wall 24 and into (threaded) receptors (not shown) within the side wall 28 can be used to facilitate compression of the o-ring and the formation of a vacuum seal. Alternately, for example, the upper wall 24 and side wall 28 can further comprise at least one hinge (not shown) and at least one latch (not shown) to facilitate compression of the o-ring, wherein closing the latch permits sealing the process chamber 20 and opening the latch permits opening the process chamber 20, i.e. the upper wall 24 serves as a process chamber lid.

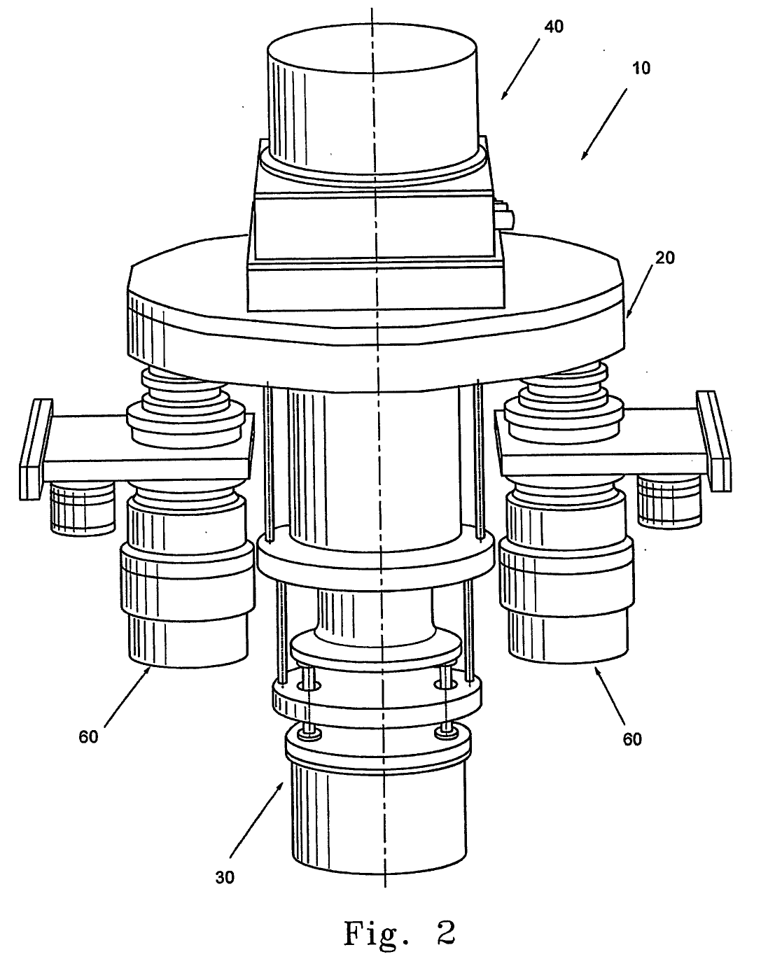

FIGS. 1 and 2 depict a cross sectional view and a perspective view of process chamber 20 and associated hardware, respectively. The upper electrode 40 and (moveable) chuck assembly 30 are depicted, as well as two pumping cells 60 attached to the chamber floor or lower wall 26. The process chamber 20 can also include a slot valve (not shown) and robot (not shown) to transfer substrates into and out of process chamber 20, and place substrates on the chuck assembly 30. The slot valve and robot are located on a rear side of the process chamber 20.

The process chamber 20 has one or more pumping ports 50 that are preferably located on a floor or lower wall 26 of the process chamber 20 adjacent to a process chamber volume 22. One or more pumping cells 60 are each connected to a respective pumping port 50. The pumping cells 60 each preferably include a turbo molecular pump (or TMP) and a gate-valve. The pumping cells can also include a butterfly valve, depending on the gate valve configuration and function. The configuration of the process chamber 20 provides for the attachment of any number of pumping cells 60 to pump gas from the process chamber volume 22 depending upon the process being performed and the geometry of the machine. The pumping ports 50 and pumping cells 60 can be provided at the bottom and/or top of the process chamber 20 as required. The proximity of the pumping cells to the process chamber volume 22 can lead to a significant improvement in process chamber conductance and, hence, pumping speed at the substrate.

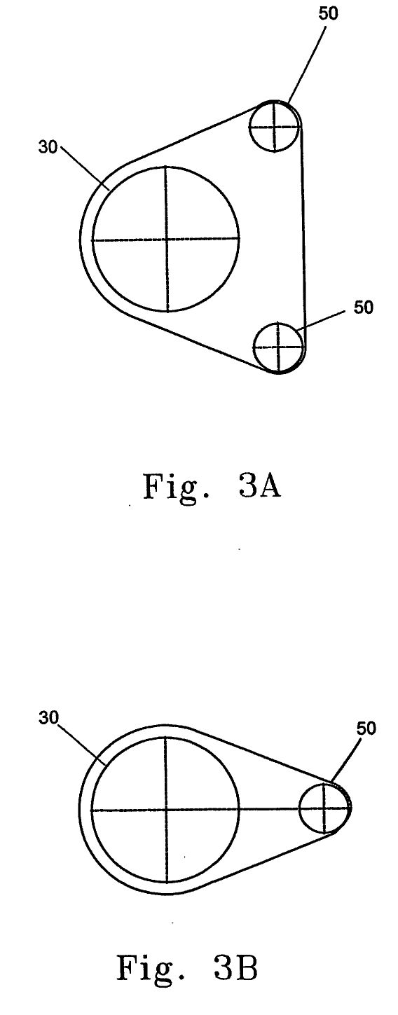

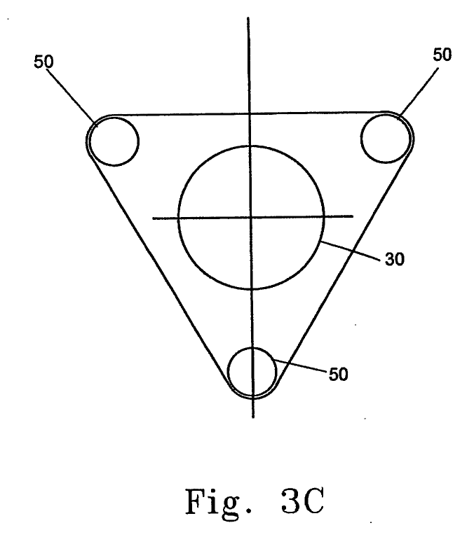

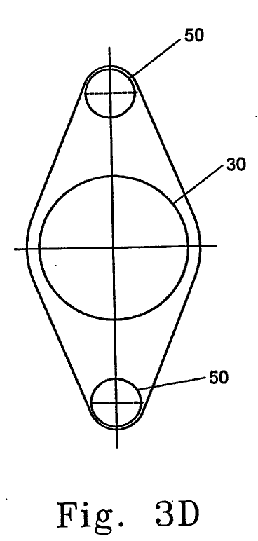

FIGS. 3A-3D are top views of various pumping port configurations with respect to a chuck assembly 30. The various configurations in FIGS. 3A-3D do not represent all the arrangements that are possible in view of the teachings of the present inventions.

In FIG. 3A, two pumping ports 50 are provided on a floor of the process chamber. The pumping ports 50 are not symmetrically positioned about the chuck assembly 30. In FIG. 3B, a single pumping port 50 is provided on the floor of the process chamber adjacent one side of the chuck assembly 30. In FIG. 3C, three pumping ports 50 are provided in a symmetrically spaced arrangement about the chuck assembly 30. The three pumping ports of FIG. 3C are arranged in a triangular configuration, spaced, for example, in the azimuthal coordinate every 120 degrees. In FIG. 3D, two pumping ports 50 are provided symmetrically spaced about a chuck assembly 30 on opposing sides thereof. Each of the pumping ports 50 depicted in FIGS. 3A-3D are preferably connected to a respective pumping cell 60, however, alternatively a pumping port 50 can be sealed using a lid such that no pumping cell is connected to the pumping port if such a pumping cell is unnecessary in any given process.

The vacuum processing apparatus 10 can comprise means for reducing an open volume within the process chamber 20. For example, a chamber liner can be configured to displace the open volume within the process chamber 20. FIG. 1 depicts a liner 25 on the upper wall 24, a liner 27 on the bottom wall 26, and a liner 29 on the side wall 28. The liners 25, 27, and 29 can, for example, reduce the size of the process chamber volume 22 within the process chamber 20, thereby decreasing the residence time of the vacuum processing apparatus 10. Alternate liners for use inside the process chamber 20 can be configured to displace more chamber volume than depicted in FIG. 1. The liners can also be configured to reduce the residence time while displacing more volume. The liners reduce the residence time of gas atoms/molecules within the processing volume 22 by reducing the volume size while maintaining the same pumping speed at the processing volume. The conductance of the processing chamber, as a whole, is improved due to the configuration wherein the vacuum pumps are located proximate the processing volume. Typically, the liners are physically changed during chamber maintenance, however movable liners are possible but they may be disadvantageous due to the complexity and the increased risk for particulate generation. If the liners are physically changed, they are inserted in sleeves that rest on shelves formed within the process chamber or among themselves without actual fastening devices. Alternately, fastening devices can be employed to affix the liners to the chamber walls.

One novelty of the present invention is an improvement in pumping speed and residence time, while lowering the overall costs to fabricate the vacuum processing apparatus 10. Another novelty is the plethora of options available in pump sizes and locations in the process chamber 20. Furthermore, the present invention advantageously provides for changes in chamber configurations to add or subtract pumping cells to an end item machine as the process or program goals change over time. Depending on the number and size of the pumping cells, the end item footprint sizes can vary from smaller than other machines to larger than other machines.

The present invention provides several advantages over other processing machine configurations. For example, the present invention provides numerous options for pumping geometries. Additionally, the pumping speeds are improved and/or the present invention provides a configuration that allows for the use of smaller and cheaper pumping cell parts. Furthermore, fabrication costs for the plasma chamber are greatly reduced. In addition, the reduced volume chamber is more environmentally friendly since less process gas is used.

The present invention further provides a method of making an improved process chamber 20 including the steps of providing one or more pumping ports 50 in the process chamber 20, and connecting a respective pumping cell 60 to each of the one or more pumping ports 50, for example, in the manner discussed above with reference to FIGS. 1 and 3A-3D. The method preferably further includes the step of making the process chamber 20 of aluminum plate stock having a thickness of about four inches.

Several problems associated with other semiconductor processing machine configurations are improved in the present invention.

First, the cost of raw materials and machining required to fabricate other process chamber configurations is very high. Material sizes can range up to thirty inches by thirty inches by twenty-four inches thick. A two-hundred millimeter chamber can cost $20,000-$30,000, or more, for material, machining and post processing. The present invention utilizes aluminum plate stock having a thickness of about four inches. Since the thickness of the raw material in the present invention is about one-sixth the thickness in other configurations, the milling depths in the present invention are much less. Therefore, the parts are much cheaper because the raw material is cheaper and the machining is simplified.

Secondly, the other configurations use large turbo molecular pumps (or TMPs) and associated gate valves. These parts are also very expensive. Large sized pumps are required to pump relatively large chamber volumes. In the present invention, the process chamber volume is less than one-third the volume in other machines. The present invention uses a finite number of smaller TMPs and associated gate valves. The sum of the cost of the smaller individual parts can be less expensive than other machine configurations with only one large TMP and gate valve. Additionally, in the present invention smaller backing pumps may be used with the smaller TMPs, thereby further reducing costs.

Thirdly, the pumping conductance in other machines tends to be poor. In other configurations, a single pumping port is located on a side wall of the process chamber. The single pumping port is connected to a plenum chamber, which in turn is attached to the gate valve and TMP. This pumping path is very tortuous and restricts the vacuum flow considerably. Accordingly, in other machines, the actual pumping speeds at the wafer are only a fraction (about 30% and less) of the rated pumping speeds of the TMPs used. The present invention has greatly improved conductance. The residence time and conductance improvement is possible because the chamber volume is reduced by a factor of three and gate valves and associated TMP(s) are located directly on the process chamber floor (or the sidewalls) adjacent to the process chamber volume, respectively. The improvement in conductance of the present invention allows for (1) better pumping speeds, (2) the use of smaller and cheaper vacuum components to obtain existing pumping speeds, or (3) both (1) and (2).

It should be noted that the exemplary embodiments depicted and described herein set forth the preferred embodiments of the present invention, and are not meant to limit the scope of the claims hereto in any way. Thus, numerous modifications and variations of the present invention are possible in light of the above teachings. It is therefore to be understood that, within the scope of the appended claims, the invention may be practiced otherwise than as specifically described herein.

1. A process chamber comprising a lower wall and a side wall, wherein said side wall has a height of at most about four inches.

2. The process chamber according to claim 1, wherein said process chamber is made of a single unit of plate stock having a thickness of about four inches.

3. The process chamber according to claim 2, wherein said plate stock is aluminum.

4. The process chamber according to claim 1, wherein said process chamber has at least one pumping port configured to receive a pumping cell.

5. The process chamber according to claim 1, wherein said process chamber has a plurality of pumping ports each configured to receive a pumping cell.

6. The process chamber according to claim 5, wherein said plurality of pumping ports are located on said lower wall of said process chamber adjacent to a process chamber volume.

7. The process chamber according to claim 5, wherein three pumping ports are provided on said lower wall of said process chamber symmetrically spaced about a chuck assembly provided within said process chamber.

8. The process chamber according to claim 1, further comprising means for reducing open volume within said process chamber.

9. The process chamber according to claim 8, wherein said means for reducing open volume is a chamber liner configured to displace open volume within said process chamber.

10. A vacuum processing apparatus comprising:
a process chamber having a plurality of pumping ports; and
a plurality of pumping cells each connected to a respective pumping port of said plurality of pumping ports.

11. The vacuum processing apparatus according to claim 9, wherein said process chamber comprises a lower wall and a side wall, the side wall having a height of at most about four inches.

12. The vacuum processing apparatus according to claim 11, wherein said process chamber is made of a single unit of plate stock having a thickness of about four inches.

13. The vacuum processing apparatus according to claim 12, wherein said plate stock is aluminum.

14. The vacuum processing apparatus according to claim 11, wherein said plurality of pumping ports are located on the lower wall of said process chamber adjacent to a process chamber volume.

15. The vacuum processing apparatus according to claim 11, wherein three pumping ports are provided on the lower wall of said process chamber symmetrically spaced about a chuck assembly provided within said process chamber.

16. The vacuum processing apparatus according to claim 15, wherein three pumping cells are connected to said process chamber, each one of said three pumping cells being connected to a respective one of said three pumping ports.

17. The vacuum processing apparatus according to claim 11, wherein two pumping ports are provided on the lower wall of said process chamber symmetrically spaced about a chuck assembly on opposing sides thereof.

18. The vacuum processing apparatus according to claim 17, wherein two pumping cells are connected to said process chamber, each one of said two pumping cells being connected to a respective one of said two pumping ports.

19. The vacuum processing apparatus according to claim 10, further comprising means for reducing open volume within said process chamber.

20. The vacuum processing apparatus according to claim 19, wherein said means for reducing open volume comprises a chamber liner configured to displace open volume within said process chamber.

21. The vacuum processing apparatus according to claim 10, wherein said process chamber facilitates the formation of plasma.

22. A method of making an improved process chamber, said method comprising the step of:
making the process chamber with a lower wall and a side wall, the side wall having a height of at most about four inches.

23. The method according to claim 22, wherein the process chamber is made of a single unit of plate stock having a thickness of about four inches.

24. The method according to claim 23, wherein the plate stock is aluminum.

25. The method according to claim 22, further comprising the step of providing in the process chamber at least one pumping port configured to receive a pumping cell.

26. The method according to claim 22, further comprising the step of providing in the process chamber a plurality of pumping ports each configured to receive a pumping cell.

27. The method according to claim 26, further comprising the step of providing the plurality of pumping ports on the lower wall of the process chamber adjacent to a process chamber volume.

28. The method according to claim 26, further comprising the steps of:
providing a chuck assembly in the process chamber; and
providing three pumping ports on the lower wall of the process chamber symmetrically spaced about the chuck assembly.

29. The method according to claim 26, further comprising the steps of:
providing an upper electrode to facilitate the formation of plasma in the process chamber.

30. The method according to claim 22, further comprising the step of providing in the process chamber a chamber liner configured to displace open volume within the process chamber.

31. A method of making an improved process chamber, said method comprising the steps of:
providing a plurality of pumping ports in the process chamber; and
connecting a respective pumping cell to each of the plurality of pumping ports.

32. The method according to claim 31, further comprising the step of making the process chamber with a lower wall and a side wall, the side wall having a height of at most about four inches.

33. The method according to claim 32, further comprising the step of making the process chamber of plate stock having a thickness of about four inches.

34. The method according to claim 33, wherein the plate stock is aluminum.

35. The method according to claim 32, further comprising the step of making the process chamber comprising a molding process.

36. The method according to claim 32, wherein said lower wall is a plate and said side wall is a rolled cylinder, further comprising the step of making the process chamber comprising welding the lower wall to the side wall.

37. The method according to claim 32, further comprising the step of providing the plurality of pumping ports on the lower wall of the process chamber adjacent to a process chamber volume.

38. The method according to claim 32, further comprising the steps of:
providing a chuck assembly in the process chamber; and
providing three pumping ports on the lower wall of the process chamber symmetrically spaced about the chuck assembly.

39. The method according to claim 38, further comprising the step of connecting three pumping cells to the process chamber, wherein each one of the three pumping cells are connected to a respective one of the three pumping ports.

40. The method according to claim 32, further comprising the steps of:
providing a chuck assembly in the process chamber; and
providing two pumping ports on the lower wall of the process chamber symmetrically spaced about the chuck assembly on opposing sides thereof.

41. The method according to claim 40, further comprising the step of connecting two pumping cells to the process chamber, wherein each one of the two pumping cells are connected to a respective one of the two pumping ports.

42. The method according to claim 31, further comprising the step of providing in the process chamber a chamber liner configured to displace open volume within the process chamber.

43. The method according to claim 31, further comprising the steps of:
providing an upper electrode to facilitate the formation of plasma in the process chamber.
